(19) United States
(12) Patent Application Publication
(10) Pub. No.: US 2006/0282999 A1
(43) Pub. Date: Dec. 21, 2006

(54) Electrodes, inner layers, capacitors and printed wiring boards and methods of making thereof - part II

(76) Inventors: Diptarka Majumdar, Cary, NC (US); Saul Ferguson, Durham, NC (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/453,387

(22) Filed: Jun. 15, 2006

Related U.S. Application Data
(60) Provisional application No. 60/692,119, filed on Jun. 20, 2005.

(51) Int. Cl. H01G 7/00; H01L 21/20

(52) U.S. Cl. 29/25.42; 438/381; 438/396; 438/706; 361/763; 29/846

(57) ABSTRACT

Disclosed is an improved method of embedding capacitors in printed wiring boards (PWB) made from thick film dielectrics and electrodes.

This application claims the benefit of U.S. Provisional Application No. 60/692,119 filed Jun. 20, 2005.

### BACKGROUND

### Technical Field

The technical field is embedded capacitors in printed wiring boards (PWB). More particularly, the technical field includes embedded capacitors in printed wiring boards made from thick film dielectrics and electrodes.

### TECHNICAL BACKGROUND OF THE INVENTION

The practice of embedding high capacitance density capacitors in printed wiring boards allows for reduced circuit size and improved circuit performance. Capacitors are typically embedded in panels that are stacked and connected by interconnection circuitry, the stack of panels forming a multilayer printed wiring board. The stacked panels can be generally referred to as “innerlayer panels.”

Passive circuit components embedded in printed wiring boards formed by fired-on-foil technology are known. “Separately fired-on-foil” capacitors are formed by depositing and drying at least one thick-film dielectric layer onto a metallic foil substrate, followed by depositing and drying a thick-film electrode material over the thick-film capacitor dielectric layer and subsequently firing the capacitor structure under copper thick-film firing conditions. U.S. Patent Application Publication Nos. U.S. 2004/0099999 A1 and U.S. 2004/023361 A1 disclose such a process.

After firing, the resulting article may be laminated to a prepreg dielectric layer, and the metallic foil may be etched to form the electrodes of the capacitor and any associated circuitry to form an inner layer panel containing thick-film capacitors. The inner layer panel may then be laminated and interconnected to other inner layer panels to form a multilayer printed wiring board.

The thick-film dielectric material should have a high dielectric constant (K) after firing. A high K thick-film dielectric paste suitable for screen printing may be formed by mixing a high dielectric constant powder (the “functional phase”) with a glass powder and dispersing the mixture into a thick-film screen-printing vehicle. The glass may be vitreous or crystalline, depending on its composition.

During firing of the thick-film dielectric material, the glass component of the dielectric material softens and flows before the peak firing temperature is reached. It coalesces and encapsulates the functional phase during the hold at peak temperature forming the fired-on-foil capacitor structure. The glass may subsequently crystallize to precipitate any desired phases.

Copper is a preferred material for forming electrodes. A thick-film copper electrode paste suitable for screen printing may be formed by mixing copper powder with a small amount of glass powder and dispersing the mixture into a thick-film screen printing vehicle. However, the large temperature coefficient of expansion (TCE) difference between the thick-film copper and the thick-film capacitor dielectric, and shrinkage differences during firing often lead to tensile stress in the dielectric just outside the periphery of the electrode. The tensile stresses may result in cracking in the dielectric around the periphery of the electrode as shown in FIG. 1A and FIG. 1B. In extreme circumstances the cracks can extend all the way down to the copper foil. Such cracking is undesirable as it may affect long term reliability of the capacitor. Alternative capacitor structure designs that eliminate the conditions that lead to such cracking would be advantageous.

A commonly assigned invention (Docket No. EL-0593 US PRV to Majumdar et al.) U.S. Provisional Application No. 60/692,119 filed Jun. 20, 2005, upon which this application claims priority to and co-authored by the present inventors, has provided novel method(s) of forming electrodes and inner layers, embedding thick-film fired-on-foil capacitors, and forming printed wiring boards (PWB) which avoid such cracking in the dielectric in addition to electrodes, inner layers, capacitors and printed wiring boards formed by these methods. However, the location of the embedded capacitor on the outermost (first and/or last) layers of a PWB and access using plated through hole (PTH) vias was not possible with the above-mentioned invention. The present invention successfully addresses these deficiencies.

### SUMMARY

Disclosed herein is a method for forming an embedded capacitor comprising the following steps:

providing a metallic foil;

forming a ceramic dielectric over the metallic foil;

forming an electrode over most of said dielectric and at least a portion of said metallic foil;

firing the capacitor structure under base metal firing conditions; and

etching the metallic foil to form a second electrode.

Further disclosed is a method of forming a capacitor comprising:

providing a metallic foil;

forming an insulating isolation layer over the metallic foil;

forming a ceramic dielectric over the metallic foil wherein the dielectric is surrounded by and in contact with an insulating isolation layer;

forming a first electrode over most or all of the dielectric, over most of the insulating isolation layer and over a portion of the metallic foil;

firing the capacitor structure under base metal firing conditions; and etching the metallic foil to form a second electrode.

In the description “firing the capacitor structure under base metal firing conditions; and etching the metallic foil to form a second electrode” the phrase

“firing the capacitor structure under base metal firing conditions” means firing in an inert atmosphere, for example argon or nitrogen, at temperatures at or greater than 750 degrees C. The firing can be done in a hot-wall or box furnace.

Further configurations of the invention are disclosed in the detailed description.

Also disclosed are capacitors formed by the above methods and other devices containing those capacitors. Such devices include, but are not limited to, interposers, printed wiring boards, multichip modules, area array packages, system-on-packages and system-inipackages.

### BRIEF DESCRIPTION OF THE DRAWINGS

The detailed description will refer to the following drawings wherein:

FIGS. 1A-1B are views illustrating cracks observed in conventional prior art designs of fired-on-foil capacitors

FIGS. 2A-2K are a series of views illustrating a method of manufacturing a printed wiring board with fired-on-foil embedded capacitors that have a printed electrode covering most of the dielectric. Some or all of the uncovered dielectric provides the insulation required between the top and bottom electrodes of the capacitors to be able to connect one electrode to a plated through hole via as shown in FIG. 2L.

FIGS. 3A-3P are a series of views illustrating a method of manufacturing a printed wiring board with fired-on-foil embedded capacitors that have an insulating isolation layer around the periphery of the dielectric and a printed electrode covering most of the isolation layer. The insulating isolation layer maybe the same material as the dielectric or a different material with enough insulation resistance to electrically isolate a pair of electrodes across its thickness.

FIG. 4 illustrates an alternative design for the thick film capacitor layout in FIG. 3.

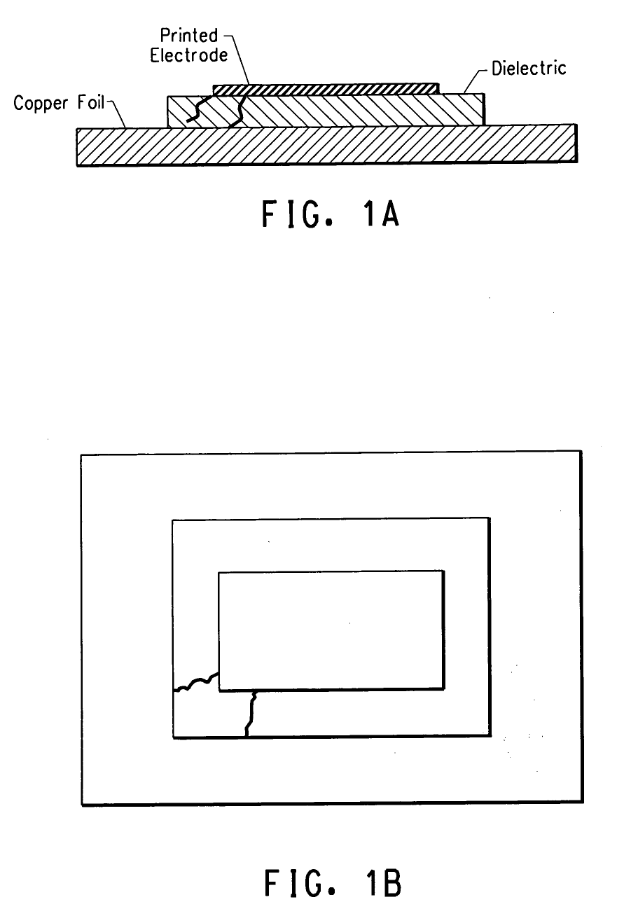

According to common practice, the various features of the drawings are not necessarily drawn to scale. Dimensions of various features may be expanded or reduced to more clearly illustrate the embodiments of the invention.

### DETAILED DESCRIPTION OF THE INVENTION

The methods and products disclosed herein exist in various configurations. According to a first embodiment, a method of making a fired-on-foil single dielectric layer capacitor structure comprises: providing a metallic foil; forming a capacitor dielectric over the metallic foil; forming a first electrode over most of the dielectric and over a portion or all of the metallic foil and firing the capacitor structure under copper thick-film firing conditions.

According to a second embodiment, a method of making a fired-on-foil single dielectric layer capacitor structure comprises: providing a metallic foil; forming an insulating isolation layer over the metallic foil; forming a capacitor dielectric over the metallic foil into the enclosure created by the insulating isolation layer; forming a first electrode over most of the dielectric and over a portion or all of the insulating isolation layer, and firing the capacitor structure under copper thick-film firing conditions.

According to a third embodiment, a method of making a fired-on-foil single dielectric layer capacitor structure comprises: providing a metallic foil; forming an insulating isolation layer over the metallic foil; forming a capacitor dielectric over the metallic foil into the enclosure created by the insulating isolation layer; forming a first electrode over most of the dielectric and over a portion or all of the insulation isolation layer and a portion of the metallic foil, and firing the capacitor structure under copper thick-film firing conditions.

According to another embodiment, a method of making a fired-on-foil embedded capacitor inner layer comprises: laminating the component side of the fired-on-foil capacitor structure to a prepreg material and etching the metallic foil to form a first and second electrode.

According to a further embodiment; a method of making a multilayer printed wiring board with a fired-on-foil embedded capacitor comprises laminating the fired-on-foil embedded capacitor inner layer to additional prepreg material and forming at least one via through the prepreg material to connect with at least one electrode.

According to the above embodiments, the electrode covers most of the dielectric and subjects the dielectric to compressive stresses thereby eliminating tensile stresses. This allows a crack free fired-on-foil capacitor to be produced and embedded inside a multilayer printed wiring board. In addition, the isolation layer may also be used as a barrier layer in the above embodiments to protect the capacitor dielectric from the etching chemicals. Capacitor reliability is thereby improved.

While the present invention is described in terms of the formation of a printed wiring board, it is understood by those skilled in the art that the embodiments of the present invention may be useful in various devices including an interposer, printed wiring board, multichip module, area array package, system-on-package, and system-in-package.

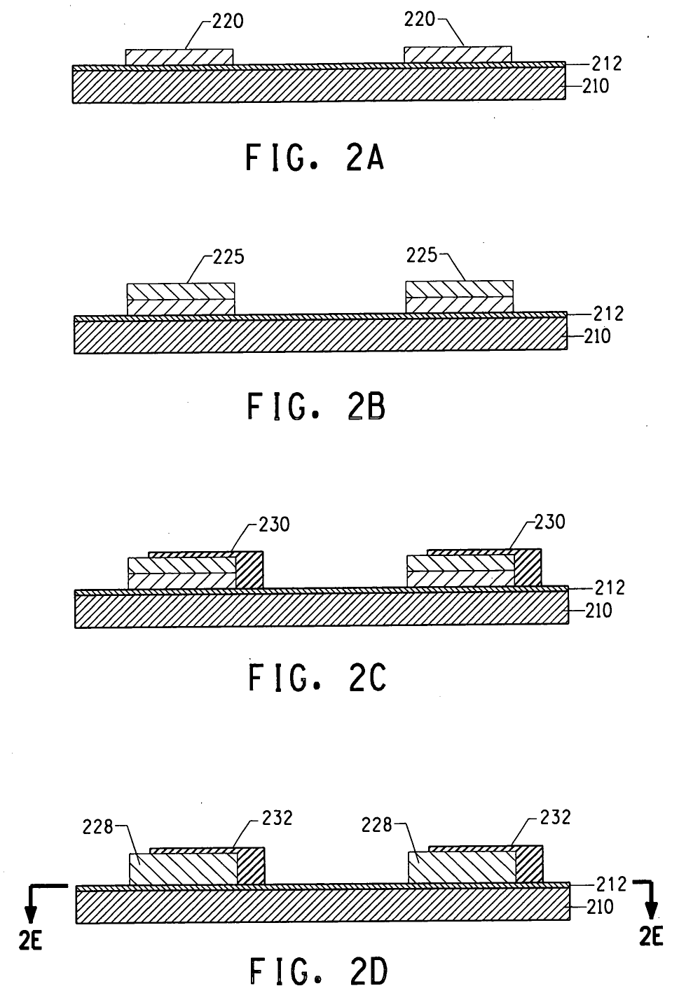

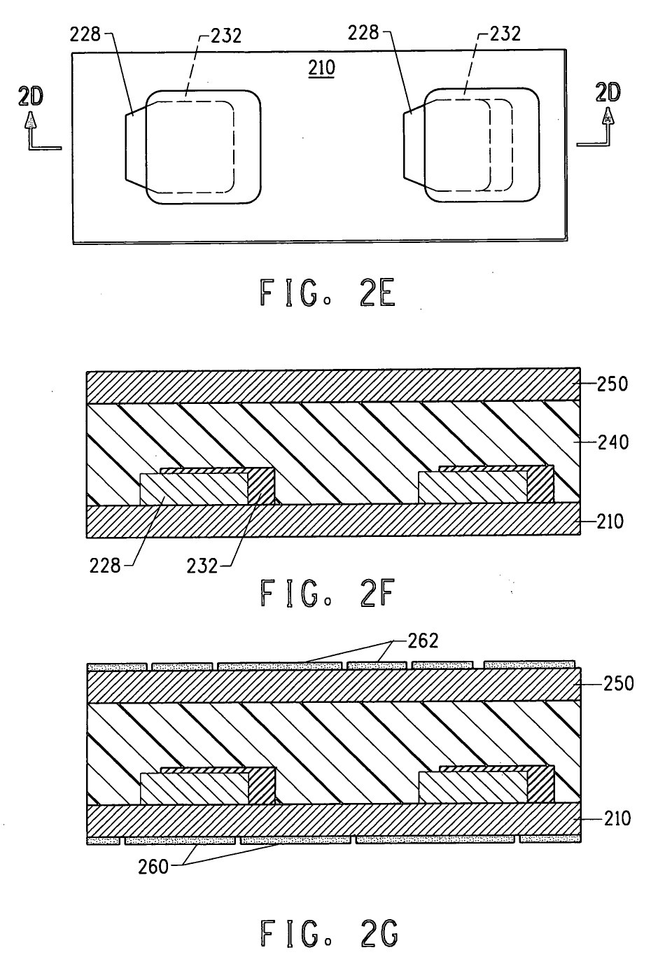

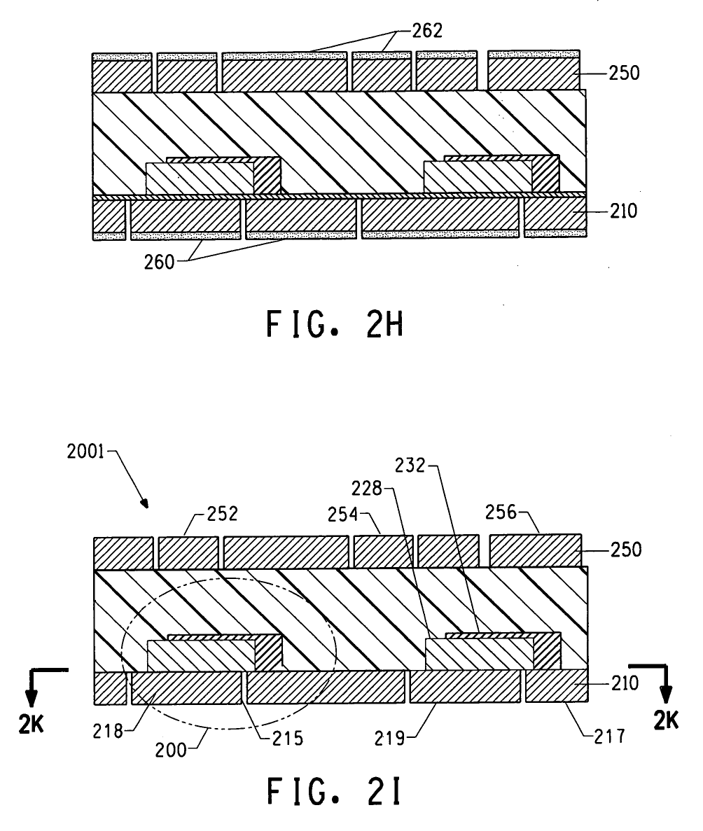

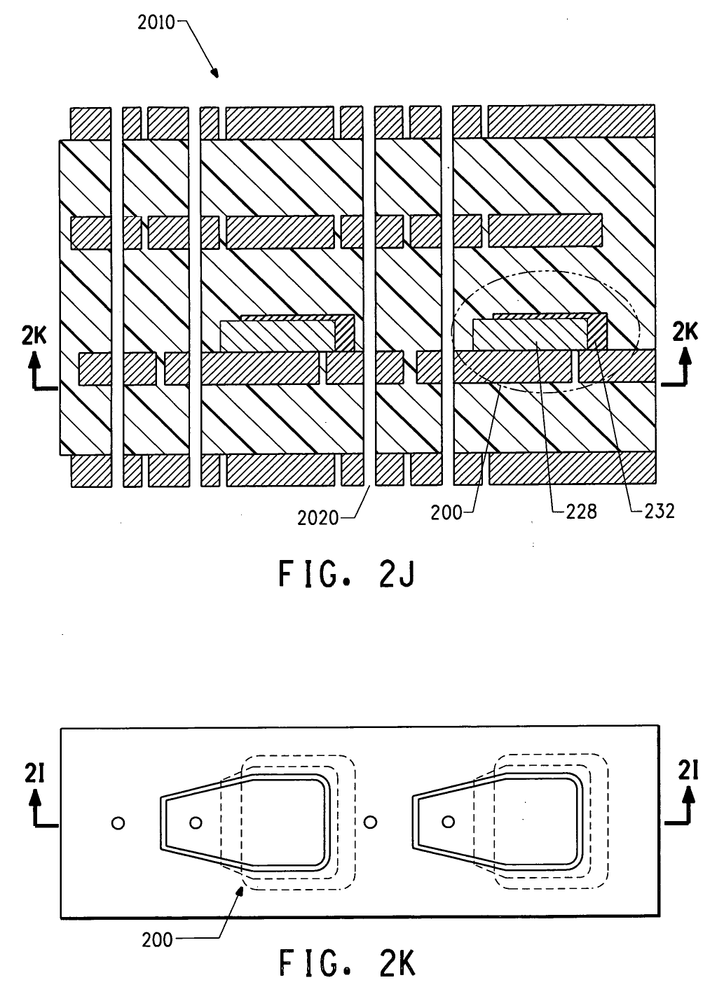

FIGS. 2A-2K illustrate a first method of manufacturing a multilayer printed wiring board 2010 (FIG. 2J) with single layer embedded capacitors having a fired-on-foil capacitor on metallic foil design wherein a printed electrode covers most of the dielectric and a portion of the metallic foil. For illustrative purposes, two embedded capacitors are illustrated as formed in FIGS. 2A-2K. However, one, two, three, or more capacitors can be formed on a foil by the methods described in this specification. The following written description is addressed to the formation of only one of the illustrated capacitors for the sake of simplicity. FIGS. 2A-2D and 2F-2I and 2J are sectional views in front elevation. FIG. 2E is a top plan view of FIG. 2D. FIG. 2K is a bottom plan view of FIG. 2J.

In FIG. 2A, a metallic foil 210 is provided. The metallic foil 210 may be of a type generally available in the industry. For example, the metallic foil 210 may be copper, copper-invar-copper, invar, nickel, nickel-coated copper, or other metals and alloys that have melting points that exceed the firing temperature for thick film pastes. Suitable foils include foils comprised predominantly of copper, such as reverse treated copper foils, double-treated copper foils, and other copper foils commonly used in the multilayer printed wiring board industry. The thickness of the metallic foil 210 may be in the range of, for example, about 1-100 microns. Other thickness ranges include 3-75 microns, and more specifically 12-36 microns. These thickness ranges correspond to between about ⅓ oz and 1 oz copper foil.

The foil 210 may, in some embodiments, be pretreated by applying and firing an underprint 212 to the foil 210. The underprint 212 is shown as a surface coating in FIG. 2A, and may be a relatively thin layer applied to the component-side surface of the foil 210. The underprint 212 adheres well to the metal foil 210 and to layers deposited over the underprint 212. The underprint 212 may be formed, for example, from a paste applied to the foil 210 that is fired at a temperature below the melting point of the foil 210. The underprint paste may be printed as an open coating over the entire surface of the foil 210, or printed over selected areas of the foil 210. It is generally more economical to print the underprint paste over selected areas of the foil 210 rather than over the entire foil 210. However, it may be preferable to coat the entire surface of the foil 210 if oxygen-doped firing is used in conjunction with a copper foil 210, because glass content in the underprint retards oxidative corrosion of the copper foil 210.

One thick-film copper paste (disclosed in U.S. application Ser. No. 10/801326; Attorney Docket No. EL-0545 to Borland et al. and is herein incorporated by reference) suitable for use as an underprint has the following composition (amounts relative by mass):

| | |
|---|---|
| Copper powder | 58.4 |
| Glass A | 1.7 |
| Cuprous oxide powder | 5.8 |
| Vehicle | 11.7 |
| TEXANOL ® solvent | 12.9 |
| Surfactant | 0.5 |
| Total | 91.0 |

In this composition,

| Glass A comprises | lead germanate of the composition Pb₅Ge₃O₁₁ | |
|---|---|---|
| Vehicle comprises: | Ethyl cellulose N200 | 11% |
| | TEXANOL ® | 89% |

| | |
|---|---|
| Surfactant comprises: | VARIQUAT ® CC-9 NS surfactant |

TEXANOL ® is available from Eastman Chemical Co.
VARIQUAT ® CC-9 NS is available from Ashland Inc.

A capacitor dielectric material 220 is deposited over the underprint 212 of the pretreated foil 210, forming the first capacitor dielectric material layer 220 as shown in FIG. 2A. The capacitor dielectric material may be, for example, a thick-film capacitor paste that is screen-printed or stenciled onto the foil 210. The first capacitor dielectric material layer 220 is then dried. In FIG. 2B, a second capacitor dielectric material layer 225 is then applied, and dried. In an alternative embodiment, a single layer of capacitor dielectric material may be deposited to an equivalent thickness of the two layers 220, 225, in a single screen-printing step. One suitable thick-film capacitor material (disclosed in U.S. application Ser. No.10/801257; Attorney Docket No. EL-0535 to Borland et al. herein incorporated by reference) for use in fired-on-foil embodiments has the following composition (amounts relative by mass):

| | |
|---|---|
| Barium titanate powder | 68.55 |
| Lithium fluoride | 1.0 |
| Barium fluoride | 1.36 |
| Zinc fluoride | 0.74 |
| Glass A | 10.25 |
| Glass B | 1.0 |
| Glass C | 1.0 |
| Vehicle | 5.9 |
| TEXANOL ® solvent | 8.7 |
| Oxidizer | 1.0 |
| Phosphate wetting agent | 0.5 |
| Total | 100.00 |

In this composition,

| Glass A comprises: | lead germanate of the composition Pb₅Ge₃O₁₁ | |
|---|---|---|
| Glass B comprises: | Pb₄BaGe_{1.5}Si_{1.5}O₁₁ | |
| Glass C comprises: | Pb₅GeSiTiO₁₁ | |
| Vehicle comprises: | Ethyl cellulose N200 | 11% |
| | TEXANOL ® solvent | 89% |
| Oxidizer comprises: | Barium nitrate powder | 84% |
| | Vehicle | 16% |

In FIG. 2C, a conductive material layer 230 is formed mostly over the second capacitor dielectric material layer 225 and over a portion of the metallic foil around the perimeter of the capacitor dielectric to form the first electrode, and dried. The conductive material layer 230 can be formed by, for example, screen-printing a thick-film metallic paste over the second capacitor dielectric material layer 225. The paste used to form the underprint 212 is also suitable for forming the conductive material layer 230.

The first capacitor dielectric material layer 220, the second capacitor dielectric material layer 225, and the conductive material layer 230 that forms the first electrode are then co-fired to sinter the resulting structure together. The post-fired structure section is shown in front elevation in FIG. 2D. Firing results in a single capacitor dielectric 228 formed from the capacitor dielectric layers 220 and 225, because the boundary between the capacitor dielectric layers 220 and 225 is effectively removed during co-firing. A top electrode 232 that mostly encapsulates the capacitor dielectric layer 228 also results from the co-firing step. The capacitor, when viewed from a top plan perspective, appears as shown in FIG. 2E. When fired on copper foil in nitrogen at approximately 900° C. for 10 minutes at peak temperature, the resulting capacitor dielectric 228 may have a dielectric constant of about 3000 and a dissipation factor of approximately 2.5%. Alternative firing conditions may be used to obtain differing material properties for the capacitor dielectric 228.

In FIG. 2F, the foil is laminated with prepreg material 240 with the first electrode 232 that covers most of the capacitor dielectric 228 facing into the prepreg material. The lamination can be performed, for example, using FR4 prepreg in standard printing wiring board processes. In one embodiment, 106 epoxy prepreg may be used. Suitable lamination conditions, for example, are 185° C. at 208 psig for 1 hour in a vacuum chamber evacuated to 28 inches of mercury. A foil 250 may be applied to an opposite side of the laminate material 240 to provide a surface for creating circuitry. A silicone rubber press pad and a smooth PTFE-filled glass release sheet may be in contact with the foils 210 and 250 to prevent the epoxy from gluing the lamination plates together. The laminate material 240 can be any type of dielectric material such as, for example, standard epoxy, high Tg epoxy, polyimide, polytetrafluoroethylene, cyanate ester resins, filled resin systems, BT epoxy, and other resins and laminates that provide insulation between circuit layers.

Referring to FIG. 2G, after lamination, a photoresist is applied to the foil 210 and the foil 250. The photoresist is imaged and developed to form the photoresist patterns 260 and 262.

Referring to FIG. 2H, the foils 210 and 250 are etched, and the photoresists 260 and 262 are stripped using, for example, standard printing wiring board processing conditions to form the article shown in FIG. 2I. The etching forms a trench 215 in the foil 210 and results in a second capacitor foil electrode 218 that is isolated from the remainder of the foil and the first electrode 232. The second capacitor foil electrode 218, the dielectric 228, and the first electrode 232 form a capacitor 200. The etching process also creates copper pads 217 and 219 from the foil 210 that may act as pads for vias to connect to the capacitor electrode 232. Circuitry 252, 254, 256 is also formed from the foil 250.

Referring to FIG. 2J, additional laminates and copper foil pairs may be laminated to the article 2001 shown in FIG. 21 and PTH vias 2020 and/or microvias drilled and plated. Photoresist may be added to the outer copper layers and imaged and developed. The outer layer copper foils are then etched and the remaining photoresist stripped, using standard printed wiring conditions, to complete the printed wiring board 2010.

FIG. 2K is a bottom plan view of the article shown in FIG. 2J. In FIG. 2K, two capacitors 200 are shown as formed from etching the trench 215 in the foil 210. This number is exemplary, however, and any number of capacitors may be formed from a foil according to the embodiments discussed herein. FIG. 2J illustrates two capacitors 200 of similar configuration, however, the present embodiment allows for the formation of capacitors of differing dimensions and/or shape.

The fabrication process described is suitable for a four metal layer printed wiring board 2010 shown in FIG. 2J with the embedded capacitors 200 in the layer adjacent to the outer layer of the printed circuit board 2010. However, the fabrication sequence may be changed and the printed wiring board may have any number of layers. The embedded capacitors according to the present embodiments can also be located at any layer in a multilayer printed circuit board. A mechanically drilled and plated through hole via may also be used to connect circuitry with the capacitor foil electrode 232.

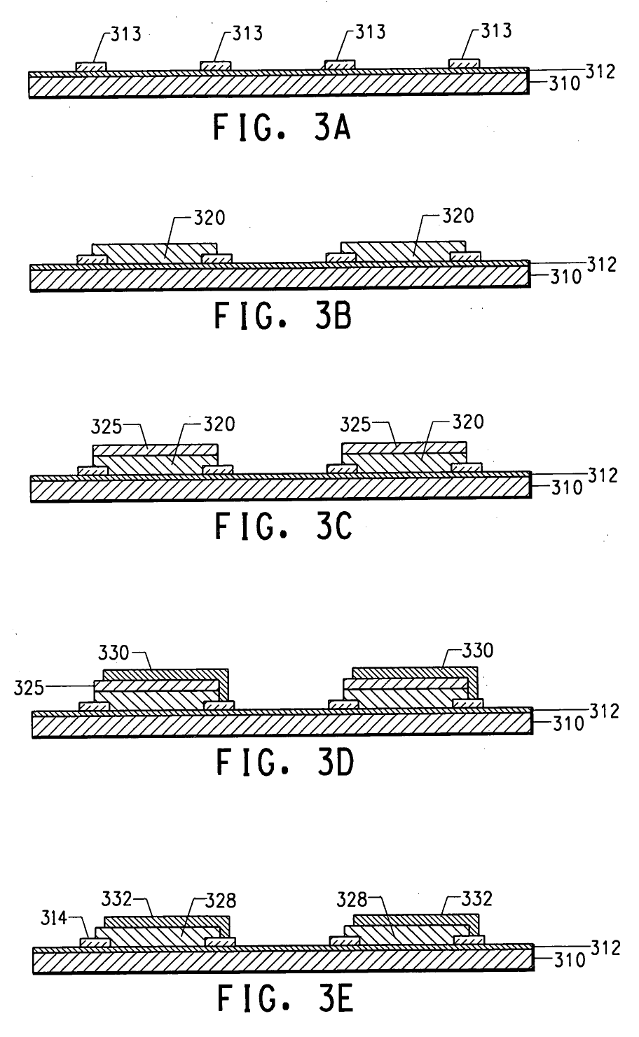

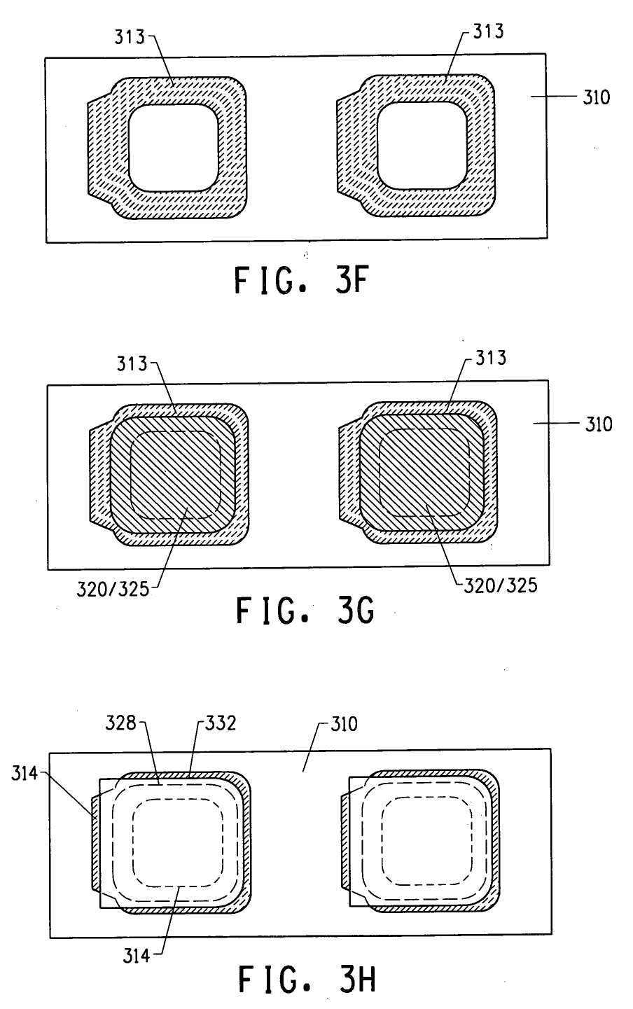

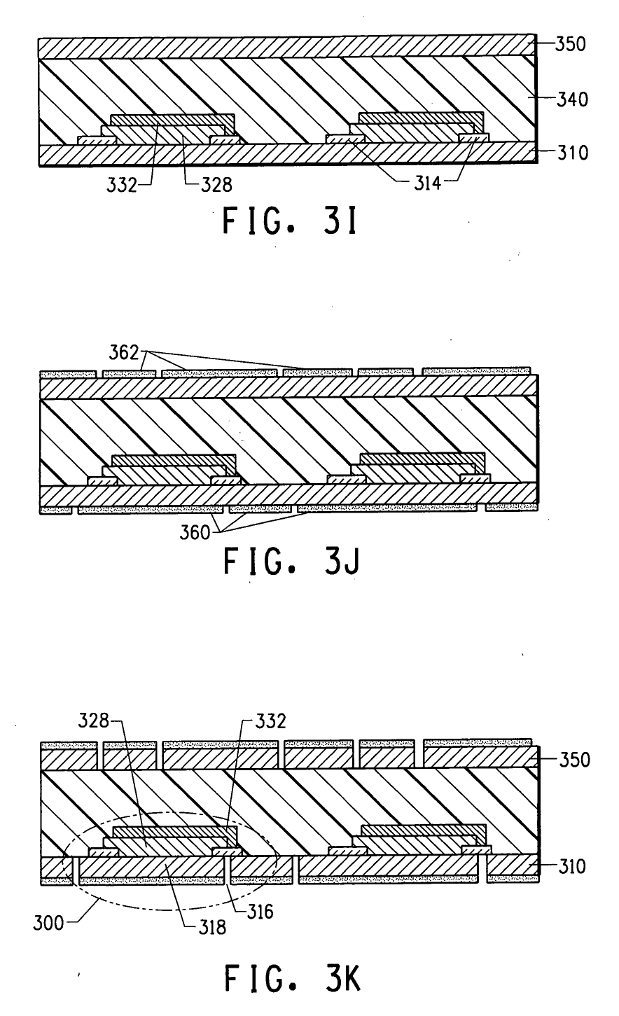

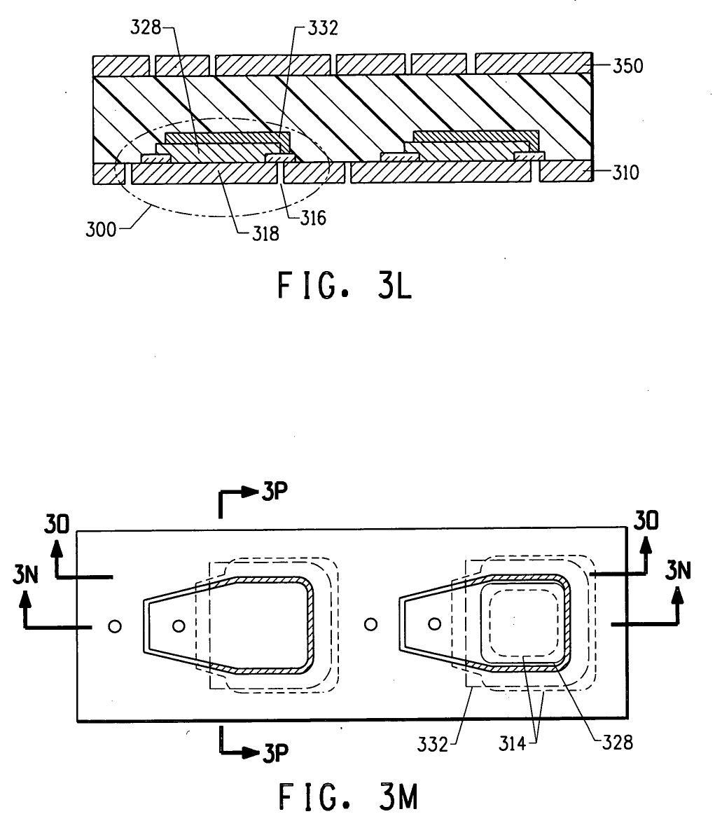

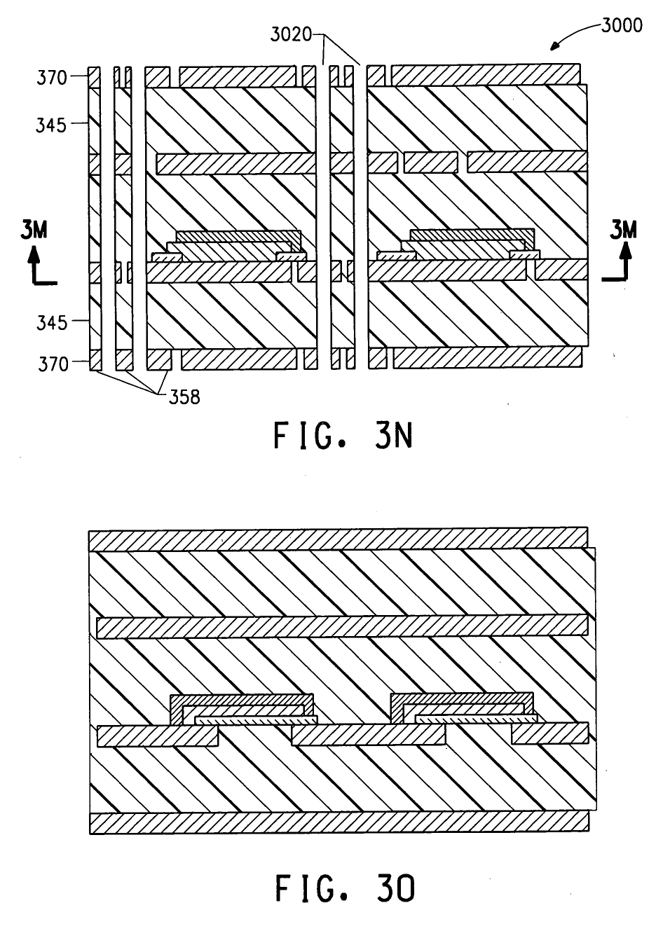

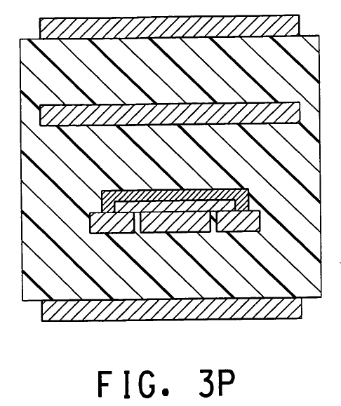

FIGS. 3A-3N illustrate a second method of manufacturing a multilayer printed wiring board 3000 (FIG. 3N) with embedded capacitors having a fired-on-foil capacitor on metallic foil design wherein a printed electrode covers most of the dielectric and a portion of an insulation isolation layer. For illustrative purposes, two embedded capacitors are illustrated as formed in FIGS. 3A-3N. However, one, two, three, or more capacitors can be formed on a foil by the methods described in this specification. The following written description is addressed to the formation of only one of the illustrated capacitors for the sake of simplicity. FIGS. 3A-3E, 3I-3L and 3N-3P are sectional views in front elevation. FIGS. 3F, 3G and 3H are top plan views of FIGS. 3A, 3C and 3E respectively. FIG. 3M is a bottom plan view of FIG. 3N.

In FIG. 3A, a metallic foil 310 is provided. The metallic foil 310 may be of a type generally described in the first embodiment and may also be pretreated similarly as described in the first embodiment by applying and firing the underprint 312 to the foil 310.

An insulating isolation layer 313 is deposited over the underprint 312 so that an enclosure is formed. A suitable insulating isolation layer may be an insulating ceramic-filled glass composition that does not crack when co-fired with copper under copper thick-film firing conditions. A top plan view of the resulting article is shown in FIG. 3F. Referring to FIG. 3B, the capacitor dielectric material as described in the first embodiment is deposited over the underprint 312 of the pretreated foil 310 into the enclosed area formed by the insulating isolation layer 313, forming a first capacitor dielectric material layer 320. The first capacitor dielectric material layer 320 is then dried. A second capacitor dielectric material layer 325 is then applied, and dried. In an alternative embodiment, a single layer of capacitor dielectric material may be deposited to an equivalent thickness of the two layers 320, 325, in a single screen-printing step. FIG. 3G is a top plan view of FIG. 3C.

In FIG. 3D, a conductive material layer 330 is formed over most of the second dielectric material layer 325 and over a portion of the insulating isolation layer 313, and dried. The conductive material layer 330 can be formed by, for example, by screen-printing the thick-film metallic paste described in the first embodiment over the second dielectric material layer 325.

The insulating isolation layer 313, the first capacitor dielectric material layer 320, the second capacitor dielectric material layer 325, and the conductive material layer 330 that forms the first electrode are then co-fired to sinter the resulting structure together. The post-fired structure section is shown in front elevation in FIG. 3E. Firing results in a single capacitor dielectric 328 formed from the capacitor dielectric layers 320 and 325, because the boundary between the capacitor dielectric layers 320 and 325 is effectively removed during co-firing. An insulating isolation layer 314, joined to the single capacitor dielectric 328, results from the firing. A top electrode 332 that mostly encapsulates the capacitor dielectric layer 328 also results from the co-firing step. The surface area of the capacitor dielectric layer 328 is smaller than that of the conductive material layer 332. When fired on copper foil in nitrogen at approximately 900° C. for 10 minutes at peak temperature, the resulting capacitor dielectric 328 may have a dielectric constant of about 3000 and a dissipation factor of approximately 2.5%. Alternative firing conditions may be used to obtain differing material properties for the capacitor dielectric 328. FIG. 3H is a top plan view of FIG. 3E.

In FIG. 3I, the foil is laminated with prepreg material 340 with the first electrode 332 that covers the capacitor dielectric 328 facing into the prepreg material. The lamination can be performed with the materials and processing as described in the first embodiment. A foil 350 may be applied to an opposite side of the laminate material 340 to provide a surface for creating circuitry.

Referring to FIG. 3J, after lamination, a photoresist is applied to the foil 310 and the foil 350. The photoresist is imaged and developed to form the photoresist pattern 360. The photoresist 362 on foil 350 may not be imaged and developed at this stage as in this manufacturing sequence, copper foil 350 is generally patterned during final outer layer processing.

The foil 310 is etched, and the photoresists 360 and 362 in FIG. 3K are stripped using, for example, standard printing wiring board processing conditions to form the article shown in FIG. 3L. The etching forms a trench 316 in the foil 310 and results in a defined second capacitor foil electrode 318 that is isolated from the remainder of the foil without the need for the etching chemicals to come in contact with the capacitor dielectric. The second capacitor foil electrode 318, the dielectric 328, and the first electrode 332 form a capacitor 300.

Referring to FIG. 3N, through-hole vias 3020 and/or microvias are drilled and plated. Photoresist may be added to the outer copper layers 370 and imaged and developed. The outer layer copper foils are then etched to create circuitry 385 and the remaining photoresist stripped, using standard printed wiring conditions, to complete the circuit board 3000, as shown in FIG. 3N.

The fabrication process described is suitable for a three metal layer printed wiring board with the embedded capacitor 300 in the middle layer of the printed circuit board 3000. However, the fabrication sequence may be changed and the printed wiring board 3000 may have any number of layers. The embedded capacitors according to the present embodiments can be located at any layer in a multilayer printed circuit board.

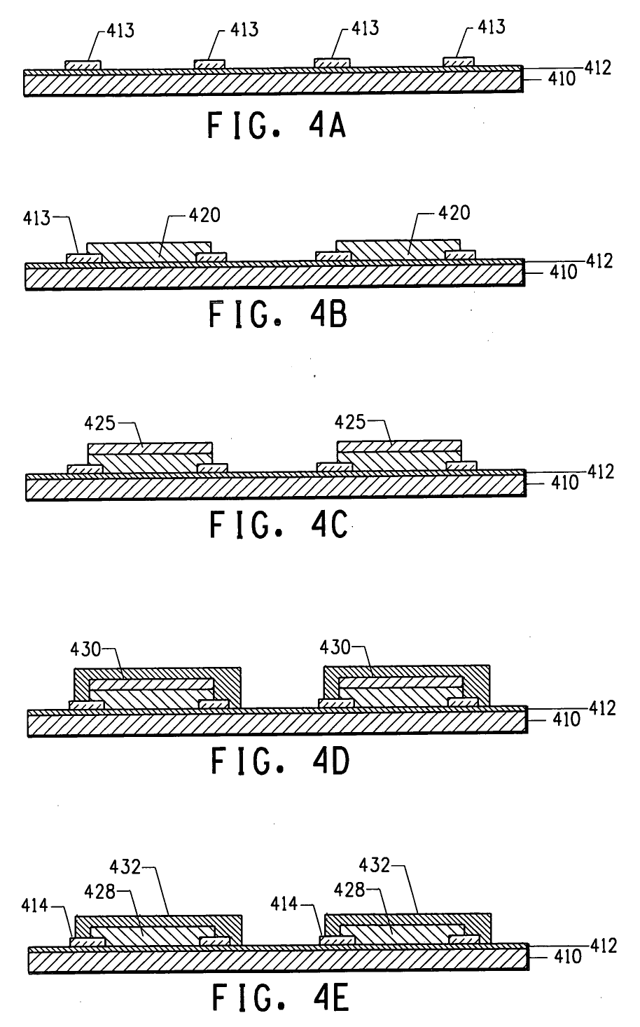

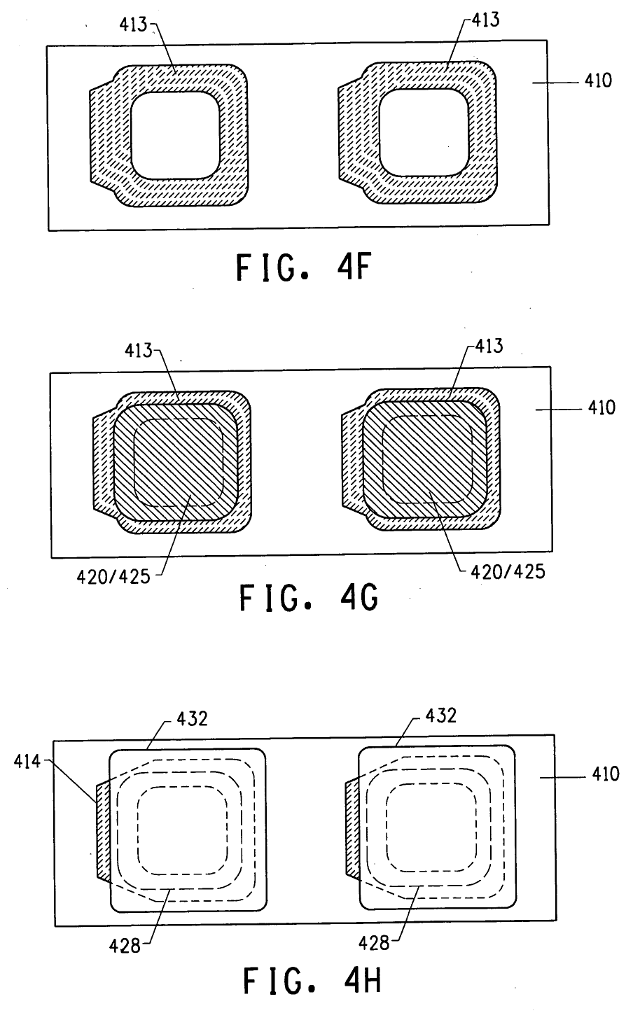

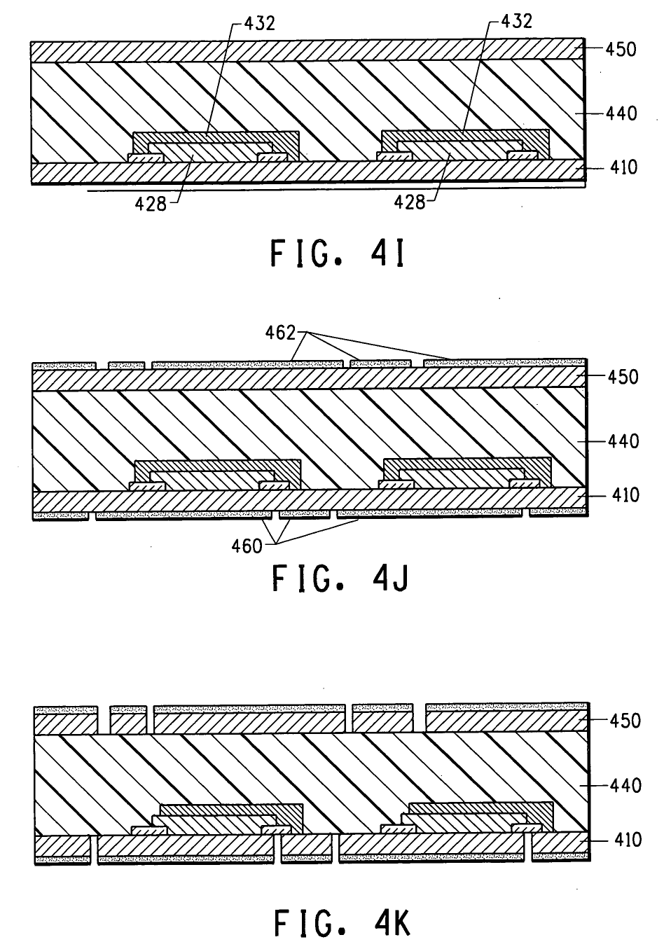

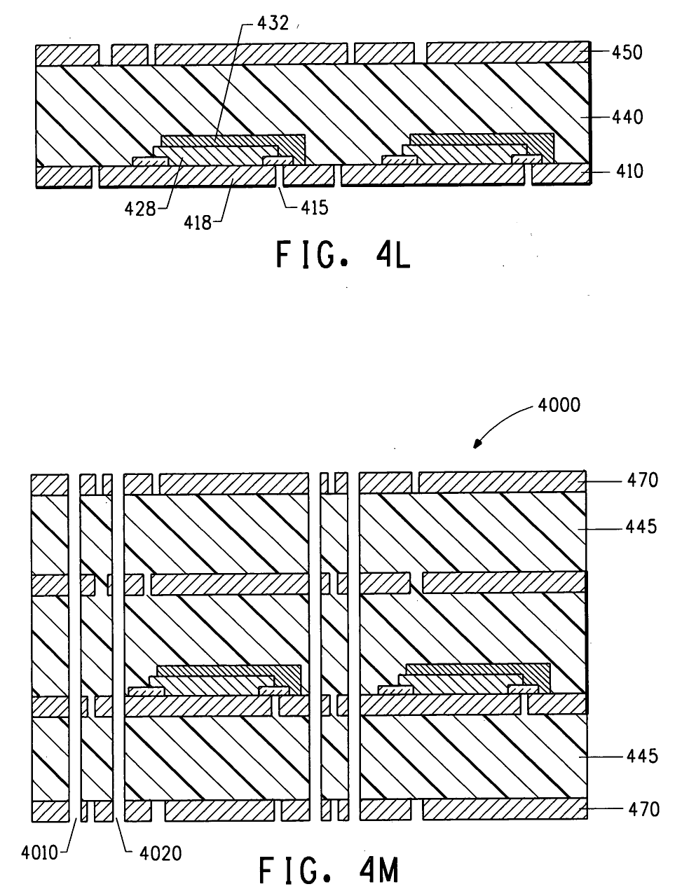

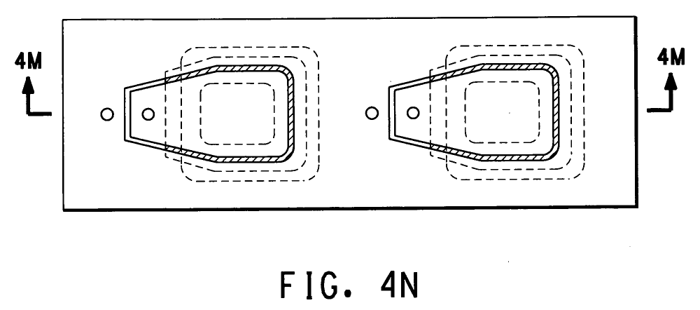

FIG. 4 illustrates an alternate design for the thick film capacitor layout in FIG. 3 where the printed top electrode covers a greater portion or all of the insulating isolation layer. However, the process for embedding the capacitors in FIG. 4 is not different from the process described by FIG. 3 and should be obvious to anyone skilled in the art. Similarly, the concepts detailed above may be easily extended to a multilayer capacitor structure by those skilled in the art.

In the above embodiments, the thick-film pastes may comprise finely divided particles of ceramic, glass, metal or other solids. The particles may have a size on the order of 1 micron or less, and may be dispersed in an “organic vehicle” comprising polymers dissolved in a mixture of dispersing agent and organic solvent.

The thick-film dielectric materials may have a high dielectric constant (K) after firing. For example, a high K thick-film dielectric may be formed by mixing a high dielectric constant powder (the “functional phase”), with dopants and a glass powder and dispersing the mixture into a thick-film screen-printing vehicle. During firing, the glass component of the capacitor material softens and flows before the peak firing temperature is reached, coalesces, and encapsulates the functional phase forming the fired capacitor composite.

High K functional phases include perovskites of the general formula ABO₃, such as crystalline barium titanate (BT), lead zirconate titanate (PZT), lead lanthanum zirconate titanate (PLZT), lead magnesium niobate (PMN) and barium strontium titanate (BST). Barium titanate is advantageous for used in fired on copper foil applications since it is relatively immune to reducing conditions used in firing processes.

Typically, the thick-film glass component of a dielectric material is inert with respect to the high K functional phase and essentially acts to cohesively bond the composite together and to bond the capacitor composite to the substrate. Preferably only small amounts of glass are used so that the dielectric constant of the high K functional phase is not excessively diluted. The glass may be, for example, calcium-aluminum-borosilicates, lead-barium-borosilicates, magnesium-aluminum-silicates, rare earth borates or other similar compositions. Use of a glass with a relatively high dielectric constant is preferred because the dilution effect is less significant and a high dielectric constant of the composite can be maintained. Lead germanate glass of the composition Pb₅Ge₃O₁₁ is a ferroelectric glass that has a dielectric constant of approximately 150 and is therefore suitable. Modified versions of lead germanate are also suitable. For example, lead may be partially substituted by barium and the germanium may be partially substituted by silicon, zirconium and/or titanium by firing the capacitor structure under base metal firing conditions; and etching the metallic foil to form a second electrode.

### EXAMPLE

PWB (printed wiring board) substrates were fabricated with embedded capacitors with the screen printed electrode mostly encapsulating the dielectric in some of them. A 4-layer design was used for PWB construction with the ceramic capacitors residing on layer 2 (L2). First, an innerlayer comprising L2/L3 was made and then laminated with layers 1 and 4 to complete the PWB stack. 1 oz. NT-TOI copper foils were used in L2. The TOI foil is a single side Zn-free treated electrodeposited foil and is designed to provide high bond strength on a wide range of organic substrates. Consequently, the foil with the capacitors did not need to be subjected to an oxide process to ensure adequate adhesion to the 1080 FR4 prepreg used to build the boards. A low lamination pressure of 125 psi was used at both innerlayer and final lamination to avoid causing any mechanical damage to the ceramic capacitor. Capacitor height was roughly 35 μm and included 10 μm of the screen printed electrode and 20 μm of the ceramic dielectric. The two plies of FR4 in each layer were at ˜150 μm in the finished boards.

The external finish on the boards was ENIG (electroless Ni/Au). All etching of copper was done with an alkaline etchant. A combination of microvias and PTH vias were used to connect the embedded capacitors to copper pads on the surfaces of the substrates.

A total of 39 finished PWB panels were fabricated. Each panel had six coupons with capacitors with 2 coupons using the capacitor design discussed in FIGS. 2A-2L of this invention. Each coupon had 20 capacitors with different areas.

The data for 20 capacitors described in FIGS. 2A-2L is presented below and indicates that the capacitor design results in functional capacitors in the finished PWB.

| | | | Insulation |
|---|---|---|---|
| | Capacitance | Dissipation | Resistance |
| Capacitor ID | (nF) | Factor (%) | (Gohm) |
| 1 | 4.74 | 4.2 | 215 |
| 2 | 4.63 | 3.9 | 219 |
| 3 | 4.69 | 4 | 211 |
| 4 | 4.78 | 4.1 | 202 |
| 5 | 4.9 | 3.8 | 0.03 |
| 6 | 5.07 | 4.3 | 201 |
| 7 | 4.93 | 4.1 | 75 |
| 8 | 5.19 | 4.6 | 201 |
| 9 | 13.23 | 4.9 | 6 |
| 10 | 13.25 | 3.4 | 78 |
| 11 | 12.14 | 3.2 | 85 |
| 12 | 12.52 | 3.4 | 8.2 |
| 13 | 12.56 | 3.4 | 49 |
| 14 | 11.46 | 3 | 89 |
| 15 | 11.37 | 2.8 | 92 |
| 16 | 12.3 | 3.4 | 87 |
| 17 | 4.68 | 3.6 | 271 |
| 18 | 12.94 | 3.7 | 89 |
| 19 | 13.34 | 3.9 | 90 |
| 20 | 4.53 | 3.4 | 279 |

The foregoing description of the invention illustrates and describes the present invention. Additionally, the disclosure shows and describes only selected preferred embodiments of the invention, but it is to be understood that the invention is capable of use in various other combinations, modifications, and environments and is capable of changes or modifications within the scope of the inventive concept as expressed herein, commensurate with the above teachings, and/or within the skill or knowledge of the relevant art.

What is claimed is:

1. A method of forming an embedded capacitor, comprising:
providing a metallic foil;
forming a ceramic dielectric over the metallic foil;
forming an electrode over most of said dielectric and at least a portion of said metallic foil;
firing the capacitor structure under base metal firing conditions; and
etching the metallic foil to form a second electrode.

2. A method of forming a capacitor, comprising:
providing a metallic foil;
forming an insulating isolation layer over the metallic foil;
forming a ceramic dielectric over the metallic foil wherein the dielectric is surrounded by and in contact with an insulating isolation layer;
forming a first electrode over most or all of the dielectric, over most of the insulating isolation layer and over a portion of the metallic foil;
firing the capacitor structure under base metal firing conditions; and
etching the metallic foil to form a second electrode.

3. A capacitor formed by the methods of claim 1 or 2.

4. A device comprising at least one capacitor of claims 1 or 2.

5. A method of making a device, comprising:
providing a metallic foil;
forming an insulating isolation layer over the metallic foil;
forming a ceramic dielectric over the metallic foil wherein the dielectric is surrounded by and in contact with an insulating isolation layer;
forming a first electrode over most or all of the dielectric, over most of the insulating isolation layer and over a portion of the metallic foil;
laminating the component side of the metallic foil to at least one prepreg material;
etching the metallic foil to form a second electrode, wherein the first encapsulating electrode, the dielectric and the second electrode form a capacitor.

6. The method of claim 5, wherein the insulation layer also acts as a barrier layer to prevent etching chemicals from coming in contact with the capacitor dielectric.

7. The method of claim 5, wherein the device is laminated to at least one additional prepreg material after etching the metallic foil.

8. The method of claim 5, comprising:
forming one or more vias in the prepreg material to connect to the capacitor wherein said vias are selected from the group comprising microvias, plated through hole vias, and combinations thereof.

9. A device formed by the method of claim 5.

10. The device of claim 9, wherein said device is selected from an interposer, printed wiring board, multichip module, area array package, system-on-package, and system-in-package.
